(19) United States
(12) Patent Application Publication
(10) Pub. No.: US 2010/0282169 A1
(43) Pub. Date: Nov. 11, 2010

(54) SUBSTRATE-SUPPORTING DEVICE, AND A SUBSTRATE-PROCESSING DEVICE HAVING THE SAME

(76) Inventors: Bum-Sul Lee, Seoul (KR); Je-Ho Chae, Incheon (KR); Seong-Min Lee, Seoul (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 12/810,894

(22) PCT Filed: Jan. 16, 2009
(86) PCT No.: PCT/KR09/00247

§ 371 Date: Jun. 28, 2010

(30) Foreign Application Priority Data
Jan. 18, 2008 (KR) 10-2008-0005600

(51) Int. Cl. C23C 16/513

(52) U.S. Cl. 118/723 R

(57) ABSTRACT

A substrate support apparatus includes an upper plate supporting a substrate, a lower plate disposed under the upper plate, an insulating member interposed between the upper plate and the lower plate, an electrode interposed between the upper plate and the insulating member to direct plasma onto the substrate supported by the upper plate, and a heater interposed between the insulating member and the lower plate to heat the substrate supported by the upper plate. The insulating member includes a material having a volume resistance greater than or equal to about 10⁶ Ω-cm at a temperature of about 400° C. to about 800° C. so as to reduce a leakage current between the heater and the electrode.

### TECHNICAL FIELD

Example embodiments of the present invention relate to an apparatus for manufacturing semiconductor devices. More particularly, example embodiments of the present invention relate to an apparatus for supporting a substrate to perform a plasma process on the substrate, and an apparatus for processing a substrate having the same.

### BACKGROUND ART

Semiconductor devices may generally be manufactured by a fabrication process for forming electrical circuit patterns on a semiconductor substrate, such as a silicon wafer, an electrical die sorting (EDS) process for inspecting electrical characteristics of the substrate on which the electrical circuit patterns are formed, and a packaging process for individualizing semiconductor chips formed on the substrate and packaging the semiconductor chips with epoxy resin.

A thin layer may be formed to form the circuit patterns on the substrate by a deposition process. Nowadays, a deposition apparatus using plasma is generally employed to improve electrical characteristics of the layer and to perform the deposition process at a relatively low temperature. For example, a plasma-enhanced chemical vapor deposition (PECVD) apparatus is generally used to form the layer.

The PECVD apparatus may include a process chamber into which a reactive gas is supplied, a plasma electrode disposed in the process chamber to generate plasma from the reactive gas so as to form a layer on a substrate, and a support sec on for supporting the substrate.

The support section may include an electrode for directing the plasma onto the substrate to improve the deposition efficiency of the layer and a heater for heating the substrate. The electrode may be grounded and the heater may be connected with a power supply.

Since a high voltage is applied to the heater, a leakage current may occur between the heater and the electrode. Accordingly, the deposition process may be performed abnormally and constituent elements of the deposition apparatus may be electrically damaged.

### DISCLOSURE

### Technical Problem

Example embodiments of the present invention provide an apparatus for supporting a substrate, which is capable of reducing a leakage current between a heater and an electrode.

Further, example embodiments of the present invention provide an apparatus for processing a substrate, which includes a substrate support section capable of reducing a leakage current between a heater and a ground electrode.

### Technical Solution

An apparatus for supporting a substrate, in accordance with an aspect of the present invention, may include an upper plate, a lower plate, an insulating member, an electrode and a heater. The upper plate may support the substrate and the lower plate may be disposed under the upper plate. The insulating member may be interposed between the upper plate and the lower plate. The electrode may be interposed between the upper plate and the insulating member and may be used to direct plasma onto the substrate supported by the upper plate. The heater may be interposed between the insulating member and the lower plate and may heat the substrate supported by the upper plate. The insulating member may include a material having a volume resistance greater than or equal to about 10⁶ Ω-cm at a temperature of about 400° C. to about 800° C. so as to reduce a leakage current between the heater and the electrode.

In accordance with some example embodiments of the present invention, the insulating member may be sintered aluminum nitride that is formed in an inert gas atmosphere under a pressure of about 0.01 ton/cm² to about 0.3 ton/cm² at a temperature of about 1,600° C. to about 1,900° C.

In accordance with some example embodiments of the present invention, the insulating member may include more than about 95 weight percent of aluminum nitride.

In accordance with some example embodiments of the present invention, the insulating member may have a thickness of about 3 mm to about 10 mm so as to reduce the leakage current between the heater and the electrode.

In accordance with some example embodiments of the present invention, each of the upper and lower plates may be a sintered ceramic.

In accordance with some example embodiments of the present invention, the heater may include an electrical resistance heating wire.

In accordance with some example embodiments of the present invention, the electrode may have a mesh-like or plate-like shape.

An apparatus for processing a substrate, in accordance with another aspect of the present invention, may include a process chamber, a substrate support section and a gas supply section. The substrate support section may be disposed in the process chamber and may be employed to support and heat the substrate. The gas supply section may supply a reactive gas into the process chamber to form a layer on the substrate and may serve as an upper electrode to form plasma from the reactive gas. The substrate support section may include an upper plate, a lower plate, an insulating member, a ground electrode and a heater. The upper plate may support the substrate and the lower plate may be disposed under the upper plate. The insulating member may be interposed between the upper plate and the lower plate. The ground electrode may be interposed between the upper plate and the insulating member and may be used to direct the plasma onto the substrate supported by the upper plate. The heater may be interposed between the insulating member and the lower plate and may heat the substrate supported by the upper plate. Particularly, the insulating member may include a material having a volume resistance greater than or equal to about 10⁶ Ω-cm at a temperature of about 400° C. to about 800° C. so as to reduce a leakage current between the heater and the ground electrode.

In accordance with some example embodiments of the present invention, the heater of the substrate support section may include an electrical resistance heating wire.

In accordance with some example embodiments of the present invention, the insulating member of the substrate support section may have a thickness of about 3 mm to about 10 mm so as to reduce the leakage current between the heater and the ground electrode.

In accordance with the example embodiments of the present invention as described above, a leakage current between a heater and an electrode may be reduced by an insulating member including a material having a volume resistance greater than or equal to about 10⁶ Ω-cm at a temperature of about 400° C. to about 800° C.

Further, the insulating member may have a thickness of about 3 mm to about 10 mm, and the insulating member may thus have an electrical resistance so as to sufficiently reduce the leakage current between the heater and the electrode.

Still further, the heater may include an electrical resistance heating wire, and the area of portions of the electrode opposite to the heater may thus be reduced, thereby reducing the leakage current between the heater and the electrode.

### ADVANTAGEOUS EFFECTS

According to the example embodiments of the present invention, when forming a thin layer on a substrate using plasma, a leakage current between a heater for heating the substrate to a process temperature and a ground electrode for forming the plasma may be sufficiently reduced by an insulating member disposed between the heater and the ground electrode. Thus, an apparatus for forming the thin layer may be prevented from being damaged due to the leakage current between the heater and the electrode. Further, because the plasma for forming the thin layer may be stably generated, the thin layer may be uniformly formed on the substrate, and electrical characteristics of the thin layer may be improved.

### DESCRIPTION OF DRAWINGS

Example embodiments of the present invention will become readily apparent along with the following detailed description when considered in conjunction with the accompanying drawings, in which:

FIG. 1 is a schematic view illustrating an apparatus for supporting a substrate in accordance with an example embodiment of the present invention;

FIG. 2 is a schematic view illustrating the heater shown in FIG. 1;

FIG. 3 is a schematic view illustrating the electrode shown in FIG. 1;

FIG. 4 is a schematic view illustrating a distance between the heater and the electrode shown in FIG. 1;

FIG. 5 is a schematic view illustrating an example of the heater shown in FIG. 1; and

FIG. 6 is a schematic view illustrating an apparatus for processing a substrate in accordance with another example embodiment of the present invention.

### BEST MODE

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It, will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present invention.

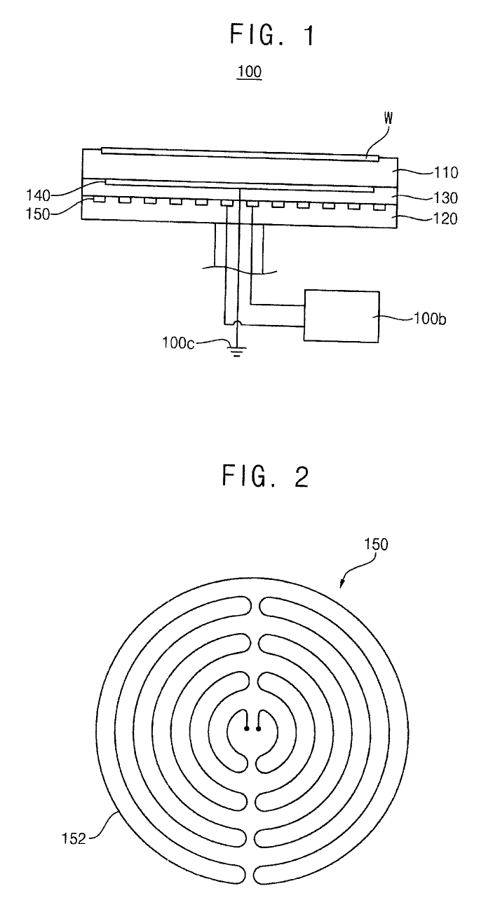

FIG. 1 is a schematic view illustrating an apparatus for supporting a substrate in accordance with an example embodiment of the present invention, and

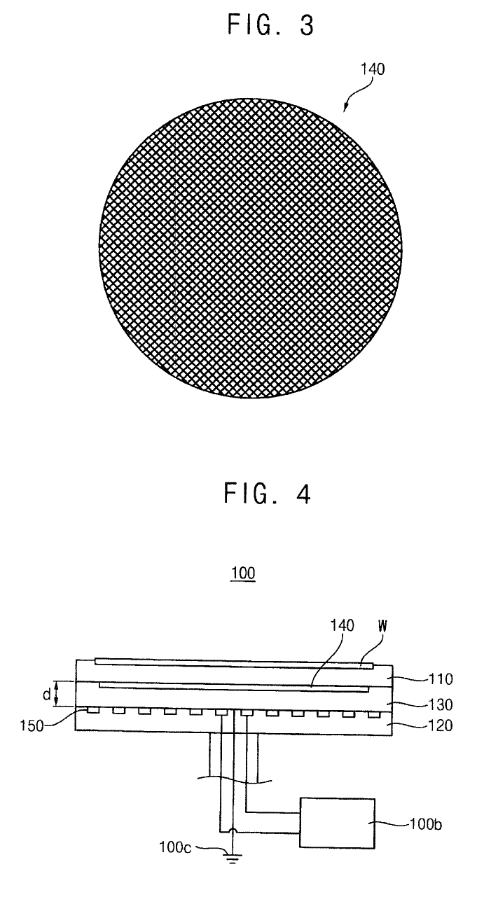

FIG. 2 is a schematic view illustrating the heater shown in FIG. 1, and FIG. 3 is a schematic view illustrating the electrode shown in FIG. 1.

Referring to FIGS. 1 to 3, an apparatus 100 for supporting a substrate W, in accordance with an example embodiment of the present invention, may include an upper plate 110 for directly supporting the substrate W, a lower plate 120 disposed under the upper plate 110, an insulating member 130 interposed between the upper plate 110 and the lower plate 120, an electrode 140 interposed between the upper plate 110 and the insulating member 130, and a heater 150 interposed between the insulating member 130 and the lower plate 120.

The substrate W to be processed may be directly supported on an upper surface of the upper plate 110. Here, the substrate W may be a silicon wafer to manufacture semiconductor devices, and a thin layer may be formed on the substrate W. However, the substrate W may not be limited by the silicon wafer. For example, the substrate W may be a flat type substrate formed of glass or quartz, which may be used to manufacture a display panel for displaying images in manufacturing a flat panel display such as a plasma display panel (PDP), a liquid crystal display (LCD), an organic light-emitting diode (OLED) display, and the like.

The upper plate 110 may be formed of a material, for example, a ceramic material, which has good heat resistance and is an insulating material. Examples of the ceramic material may include aluminum nitride (AlN), silicon nitride (Si₃N₄), silicon carbide (SiC), boron nitride (BN), aluminum oxide (Al₂O₃), and the like. These materials may be used alone or in a combination thereof. Further, the upper plate 110 may be formed by a sintering process using a ceramic powder.

Thus, when forming a thin layer on the substrate W, which is placed on the upper plate 110, using plasma, the substrate W may be stably heated on the upper plate 110, and electrical interference between the plasma and the upper plate 110 may be prevented.

The lower plate 120 may be disposed under the upper plate 110 and may be formed of the same material as the upper plate 110. Thus, further detailed descriptions for the lower plate 120 will be omitted.

The upper plate 110 and the lower plate 120 may be disposed opposite to each other, and the insulating member 130 may be interposed therebetween. That is, the lower plate 120, the insulating member 130 and the upper plate 110 may be stacked in order and may be combined with one another.

Further, the insulating member 130 may be interposed between the electrode 140 and the heater 150 to electrically insulate the electrode 140 from the heater 150.

Thus, it is desirable that the insulating member 130 have a sufficiently high electrical resistance. Particularly, the insulating member 130 may include a material having a volume resistance greater than or equal to about 10^{b} Ω-cm at a temperature of about 400° C. to about 800° C. Meanwhile, the volume resistance of a material generally becomes lower as a temperature becomes higher. Thus, the material used for the insulating member 130 may have a relatively high volume resistance at a temperature lower than about 400° C. in comparison with that at the temperature of about 400° C. to about 800° C.

For example, the insulating member 130 may be sintered aluminum nitride. The sintered aluminum nitride may be formed by a sintering process using an aluminum nitride powder. The sintering process for forming the insulating member 130 may be performed in an inert gas atmosphere including nitrogen, argon, or the like. Particularly, the sintering process may be performed under a pressure of about 0.01 ton/cm² to about 0.3 ton/cm² at a temperature of about 1,600° C. to about 1,900° C. to thereby allow the insulating member 130 to have a sufficiently high volume resistance so that the electrode 140 may be sufficiently insulated from the heater 150 by the insulating member 130.

The insulating member 130, i.e., the sintered aluminum nitride, may include more than about 95 weight percent of aluminum nitride.

Alternatively, the insulating member 130 may be formed of the same material as that of the upper plate 110 or the lower plate 120. In such a case, the upper plate 110, the lower plate 120 and the insulating member 130 may be formed of a ceramic material having a volume resistance greater than or equal to about 10⁶ Ω-cm at a temperature of about 400° C. to about 800° C.

The electrode 140 may be interposed between the upper plate 110 and the insulating member 130. The electrode 140 may be electrically connected with an external ground 100c. The electrode 140 may be formed of a metal having good conductivity. For example, the electrode 140 may include tantalum (Ta), tungsten (W), molybdenum (Mo), nickel (Ni), and the like, and an alloy thereof may be used for the electrode 140.

When forming plasma to form a thin layer on the substrate W using high frequency power, e.g., radio frequency (RF) power, the electrode 140 may provide a reference potential for forming the plasma. Further, the electrode 140 may be used to direct the plasma onto the substrate W while forming the thin layer.

The electrode 140 may have a mesh-like shape as shown in FIG. 3. Alternatively, the electrode 140 may have a plate-like shape. The electrode 140 may have a size corresponding to that of the substrate W placed on the upper plate 110.

The electrode 140 may be placed on the insulating member 130 when the insulating member 130 is formed. Particularly, the electrode 140 may be placed on a powder material for forming the insulating member 130 when a sintering process for forming the insulating member 130 is performed. Alternatively, the electrode 140 may be placed beneath a ceramic powder forming the upper plate 110 when a sintering process for forming the upper plate 110 is performed so that the electrode 140 may be placed on a lower surface of the upper plate 110. Further, the upper plate 110 and the insulating member 130 may be individually formed. When the upper plate 110 and the insulating member 130 are combined with each other, the electrode 140 may be interposed therebetween.

The heater 150 may be used to heat the substrate W. Particularly, the heater 150 may be electrically connected with a power supply 100b.

The heater 150 may include an electrical resistance heating wire. That is, the heater 150 may be formed of a metal generating heat using driving power, which is provided from the power source 100b. For example, the heater 150 may include tantalum (Ta), tungsten (W), molybdenum (Mo), nickel (Ni), and the like, and an alloy thereof may be used for the electrode 150.

The heater 150 may be placed on the lower plate 120 when the lower plate 120 is formed. That is, the heater 150 may be placed on a ceramic powder for forming the lower plate 120 when a sintering process for forming the lower plate 120 is performed. Alternatively, the heater 150 may be placed beneath the powder material forming the insulating member 130 when a sintering process for forming the insulating member 130 is performed so that the heater 150 may be placed on a lower surface of the insulating member 130. Further, the insulating member 130 and the lower plate 120 may be individually formed. When the insulating member 130 and the lower plate 120 are combined with each other, the heater 150 may be interposed therebetween.

As shown in FIG. 2, the heater 150 may be disposed to correspond to the substrate W, which is placed on the upper plate 110, and may include an electrical resistance heating wire 152 disposed at regular intervals. For example, the electrical resistance heating wire 152 may have a concentric circle structure, when the substrate W is circular, for example, a silicon wafer. Thus, the heater 150 may uniformly heat the substrate W.

As described above, the substrate support apparatus 100, in accordance with the example embodiments of the present invention, may sufficiently insulate the heater 150 from the electrode 140 in a low temperature process as well as a high temperature process, because the insulating member 130 for insulating the heater 150 from the electrode 140 has a volume resistance greater than or equal to about 10⁶ Ω-cm at a temperature of about 400° C. to about 800° C. Thus, a leakage current may be sufficiently reduced between the heater 150 and the electrode 140.

FIG. 4 is a schematic view illustrating a distance between the heater and the electrode shown in FIG. 1.

Referring to FIG. 4, it is desirable that the insulating member 130 have a thickness of about 3 mm to about 10 mm so as to sufficiently reduce the leakage current between the electrode 140 and the heater 150. In such a case, it is desirable that the insulating member 130 be formed of a material having a volume resistance greater than or equal to about 10⁶ Ω-cm at a temperature of about 400° C. to about 800° C. For example, the insulating member 130 may be sintered aluminum nitride, which may be formed in an inert gas atmosphere under a pressure of about 0.01 ton/cm² to about 0.3 ton/cm² at a temperature of about 1,600° C. to about 1,900° C.

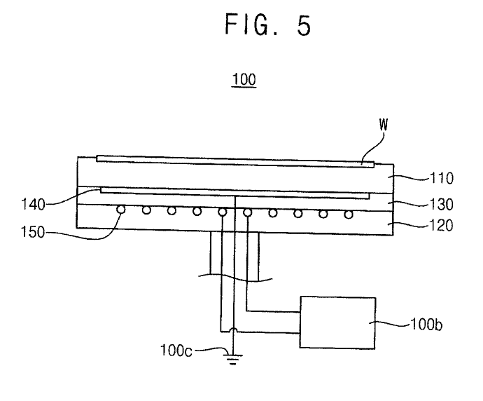

FIG. 5 is a schematic view illustrating an example of the heater shown in FIG. 1.

Referring to FIG. 5, the heater 150 may include an electrical resistance heating wire. In such a case, it is desirable that the electrical resistance heating wire have a circular cross-section to reduce the leakage current between the heater 150 and the electrode 140. The leakage current may be reduced between the heater 150 and the electrode 140 by increasing a distance between the heater 150 and the electrode 140.

When the electrical resistance heating wire has the circular cross-section, distances between side portions of the electrical resistance heating wire and the electrode 140 may be increased, and an average distance between the heater 150 and the electrode 140 may thus be increased. As a result, an electrical resistance may be increased between the heater 150 and the electrode 140, and the leakage current may thus be reduced between the heater 150 and the electrode 140.

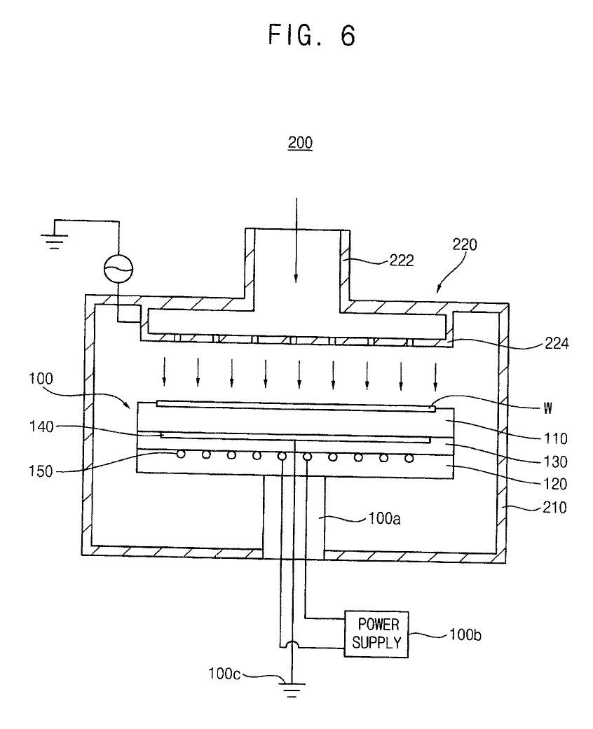

FIG. 6 is a schematic view illustrating an apparatus for processing a substrate in accordance with another example embodiment of the present invention.

Referring to FIG. 6, an apparatus 200 for processing a substrate, in accordance with another example embodiment of the present invention, may include a process chamber 210 for providing a process space to process a substrate W to be processed, a substrate support section 100 for supporting and heating the substrate W, and a gas supply section 220 for supplying a reactive gas into the process chamber 210.

The gas supply section 220 may include a gas inlet 222 connected to the process chamber 210. The reactive gas may include a source gas for forming a thin layer on the substrate W. The source gas may be supplied into the process chamber along with a carrier gas. For example, the source gas may include a silane (SiH₄), nitrogen dioxide (NO₂), ammonia (NH₃), and the like. These source gases may be used alone or in a combination thereof. An inert gas such as argon (Ar), nitrogen (N₂), and the like may be used as the carrier gas.

The substrate support section 100 may be disposed in the process chamber 210, and the substrate W may be supported by the substrate support section 100. The substrate support section 100 may include an upper plate 110 to directly support the substrate W, a lower plate 120 disposed under the upper plate 110, an insulating member 130 interposed between the upper plate 110 and the lower plate 120, a ground electrode 140 interposed between the upper plate 110 and the insulating member 130 to direct plasma onto the substrate W, and a heater 150 interposed between the insulating member 130 and the lower plate 120 to heat the substrate W.

Meanwhile, the substrate process apparatus 200 may further include a support shaft 100a for supporting the substrate support section 100. Here, the heater 150 and the ground electrode 140 may be electrically connected with a power supply 100b and a ground 100c.

Further detailed descriptions of the substrate support section 100 will be omitted because these are identical or similar to those of the substrate support apparatus already described with reference to FIGS. 1 to 5.

The gas supply section 220 may include a shower head 224 disposed at upper portion in the process chamber 210. The shower head 224 may have a plurality of holes to supply the reactive gas onto the substrate W and may be connected with a gas source through the gas inlet 222.

Further, the gas supply section 220 may serve as an upper electrode to form the plasma from the reactive gas. That is, the plasma may be generated by a potential difference between the upper electrode and the ground electrode 140.

When forming the thin layer on the substrate W using the plasma, the substrate W may be heated to a predetermined process temperature by the heater 150. In such a case, a leakage current may be sufficiently reduced between the heater 150 and the ground electrode 140 because the insulating member 130 may be formed of a material having a volume resistance greater than or equal to about 10⁶ Ω-cm at a temperature of about 400° C. to about 800° C. and may have a thickness of about 3 mm to about 10 mm as described above.

### INDUSTRIAL APPLICABILITY

According to the example embodiments of the present invention, when forming a thin layer on a substrate using plasma, a leakage current between a heater for heating the substrate to a process temperature and a ground electrode for forming the plasma may be sufficiently reduced by an insulating member disposed between the heater and the ground electrode.

Thus, an apparatus for forming the thin layer may be prevented from being damaged due to the leakage current between the heater and the electrode. Further, because the plasma for forming the thin layer may be stably generated, the thin layer may be uniformly formed on the substrate, and electrical characteristics of the thin layer may be improved.

Although the exemplary embodiments of the present invention have been described, it is understood that the present invention should not be limited to these exemplary embodiments but various changes and modifications can be made by one skilled in the art within the spirit and scope of the present invention as hereinafter claimed.

1. An apparatus for supporting a substrate comprising:
an upper plate supporting the substrate;
a lower plate disposed under the upper plate;
an insulating member interposed between the upper plate and the lower plate;
an electrode interposed between the upper plate and the insulating member to direct plasma onto the substrate supported by the upper plate; and
a heater interposed between the insulating member and the lower plate to heat the substrate supported by the upper plate,
wherein the insulating member comprises a material having a volume resistance greater than or equal to about 10⁶ Ω-cm at a temperature of about 400° C. to about 800° C. so as to reduce a leakage current between the heater and the electrode.

2. The apparatus of claim 1, wherein the insulating member is sintered aluminum nitride that is formed in an inert gas atmosphere under a pressure of about 0.01 ton/cm² to about 0.3 ton/cm² at a temperature of about 1,600° C. to about 1,900° C.

3. The apparatus of claim 2, wherein the insulating member comprises more than about 95 weight percent of aluminum nitride.

4. The apparatus of claim 1, wherein the insulating member has a thickness of about 3 mm to about 10 mm so as to reduce the leakage current between the heater and the electrode.

5. The apparatus of claim 1, wherein each of the upper and lower plates includes sintered ceramics.

6. The apparatus of claim 1, wherein the heater includes an electrical resistive heating wire.

7. The apparatus of claim 6, wherein the electrode is shaped into a mesh or a plate.

8. An apparatus for processing a substrate comprising:
a process chamber;
a substrate support section disposed in the process chamber to support and heat the substrate; and
a gas supply section supplying a reactive gas into the process chamber to form a layer on the substrate and serving as an upper electrode to form plasma from the reactive gas,
wherein the substrate support section comprises:
an upper plate supporting the substrate;
a lower plate disposed under the upper plate;
an insulating member interposed between the upper plate and the lower plate;
a ground electrode interposed between the upper plate and the insulating member to direct the plasma onto the substrate supported by the upper plate; and
a heater interposed between the insulating member and the lower plate to heat the substrate supported by the upper plate, and
the insulating member comprises a material having a volume resistance greater than or equal to about 10⁶ Ω-cm at a temperature of about 400° C. to about 800° C. so as to reduce a leakage current between the heater and the ground electrode.

9. The apparatus of claim 8, wherein the heater of the substrate support section comprises an electrical resistive heating wire.

10. The apparatus of claim 8, wherein the insulating member of the substrate support section has a thickness of about 3 mm to about 10 mm so as to reduce the leakage current between the heater and the ground electrode.
